(19) United States
(12) Patent Application Publication
(10) Pub. No.: US 2009/0121252 A1
(43) Pub. Date: May 14, 2009

(54) METHOD FOR MANUFACTURING FLIP-CHIP LIGHT EMITTING DIODE PACKAGE

(76) Inventors: Hung-Tsung Hsu, Taoyuan City (TW); Hsien-Chin Kung, Taoyuan City (TW)

Correspondence Address: HDLS Patent & Trademark Services, P.O. BOX 220746, CHANTILLY, VA, 20153-0746, US

(21) Appl. No.: 11/939,836

(22) Filed: Nov. 14, 2007

(51) Int. Cl. H01L 33/00

(52) U.S. Cl. 257/99; 438/26; 257/E33.001

(57) ABSTRACT

A method for manufacturing flip-chip light emitting diode (LED) package fabricates a silicon submount with at least one groove by wet etching. Two vias are defined on base of the groove, wherein each via has a contact pad thereon and a bottom electrode on bottom thereof. An LED die is flip-chip mounted in the groove with the electrodes thereof electrically connected to the contact pads. A protective glue is applied to fill the groove and provides a flat top face. A phosphor layer is formed on the flat top face by printing. The phosphor layer is formed with excellent uniformity due to the flat top face, and provides uniform wavelength conversion effect. Alternatively, a phosphor plate is manufactured in advance and selected with desired color temperature parameter. The phosphor plate with desired color temperature parameter is attached to the flat top face of the protective glue instead of printing.

### BACKGROUND OF THE INVENTION

1. Field of the Invention

The present invention relates to a method of manufacturing flip-chip light emitting diode package, especially to a method of manufacturing flip-chip light emitting diode package with uniform phosphor layer.

2. Description of Prior Art

Light emitting diode (LED) has the advantages of high efficiency and low cost because LED can be manufactured with direct-bandgap semiconductor and standard semiconductor manufacture process. Moreover, blue LEDs are developed with enhanced yield and power. Therefore, LED is promising for general lighting and backlight application.

FIG. 1 shows a prior art high-power LED package disclosed by US patent publication No. 20050274959. This high-power LED package is used to enclose a high-power LED die 401. As shown in this figure, the high-power LED package mainly comprises a silicon submount 402, a heat-dissipation stage 409 and a focusing lens 413. The silicon submount 402 comprises a concave groove and electrode (not labeled) formed in the concave groove. The LED die 401 is flip-chip mounted in the concave groove and electrically connected to the electrodes in the concave groove by soldering pastes 414a and 414b. The electrodes in the concave groove are electrically connected to the external electrodes 406a and 406b outside the heat-dissipation stage 409 through soldering wires 412a and 412b to power the high-power LED die 401 by external power source. The focusing lens 413 is arranged atop the heat-dissipation stage 409 to focus the light emitted from the LED die 401.

However, the above-mentioned prior art high-power LED package has the following disadvantages:

In this package, the phosphor is mixed with epoxy and then the mixture is filled into the groove by dispenser. The uniformity of the phosphor is difficult to control and the emitted light from the high-power LED is not uniform.

Moreover, the electrodes of the LED are electrically connected to the external electrodes by wire bonding process. The process is complicated and is difficult provide surface mount device (SMD).

### SUMMARY OF THE INVENTION

It is the object of the present invention to a method of manufacturing flip-chip light emitting diode package with uniform phosphor layer and ease for SMD.

Accordingly, the present invention provides a method of manufacturing flip-chip light emitting diode package.

A silicon submount with at least one groove is formed by wet etching. Two vias are defined on base of the groove, wherein each via has a contact pad thereon and a bottom electrode on bottom thereof. An LED die is flip-chip mounted in the groove with the electrodes thereof electrically connected to the contact pads. A protective glue is applied to fill the groove and provides a flat top face. A phosphor layer is formed on the flat top face by printing. The phosphor layer is formed with excellent uniformity due to the flat top face, and provides uniform wavelength conversion effect.

Alternatively, a phosphor plate is manufactured in advance and selected with desired color temperature parameter. The phosphor plate with desired color temperature parameter is attached to the flat top face of the protective glue instead of printing.

### BRIEF DESCRIPTION OF DRAWING

The features of the invention believed to be novel are set forth with particularity in the appended claims. The invention itself however may be best understood by reference to the following detailed description of the invention, which describes certain exemplary embodiments of the invention, taken in conjunction with the accompanying drawings in which:

FIG. 1 shows a prior art high-power LED package.

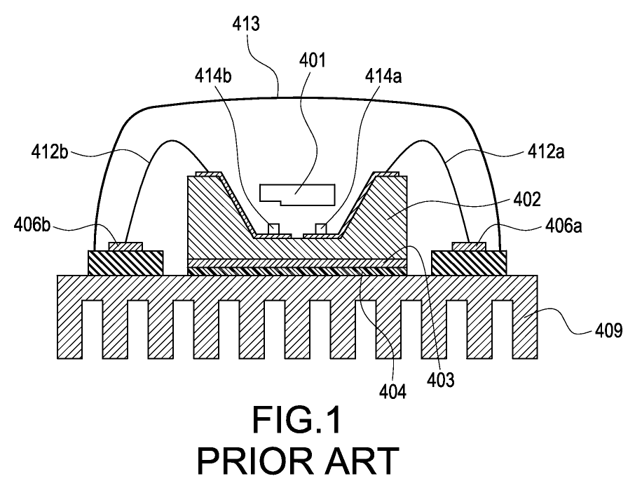

FIG. 2 shows the flowchart of the method for manufacturing flip-chip light emitting diode package according to the first preferred embodiment of the present invention.

FIGS. 3A to 3G are sectional views corresponding to steps in FIG. 2.

FIG. 4 shows an LED package according to the present invention.

FIG. 5 shows the flowchart of the method for manufacturing flip-chip light emitting diode package according to the second preferred embodiment of the present invention.

FIGS. 6A and 6B show the electrodes on the LED.

FIG. 7 shows the top view of the vias.

### DETAILED DESCRIPTION OF THE INVENTION

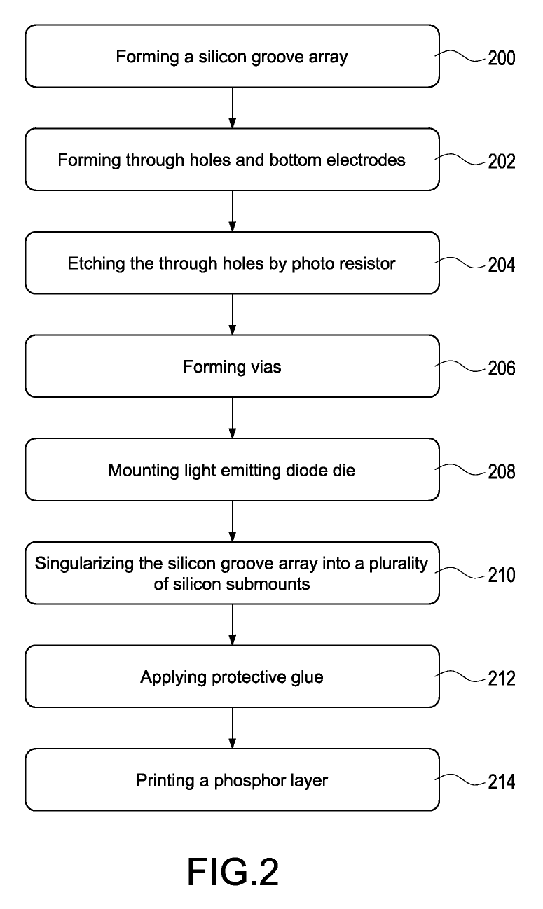

FIG. 2 shows the flowchart of the method for manufacturing flip-chip light emitting diode package according to the first preferred embodiment of the present invention.

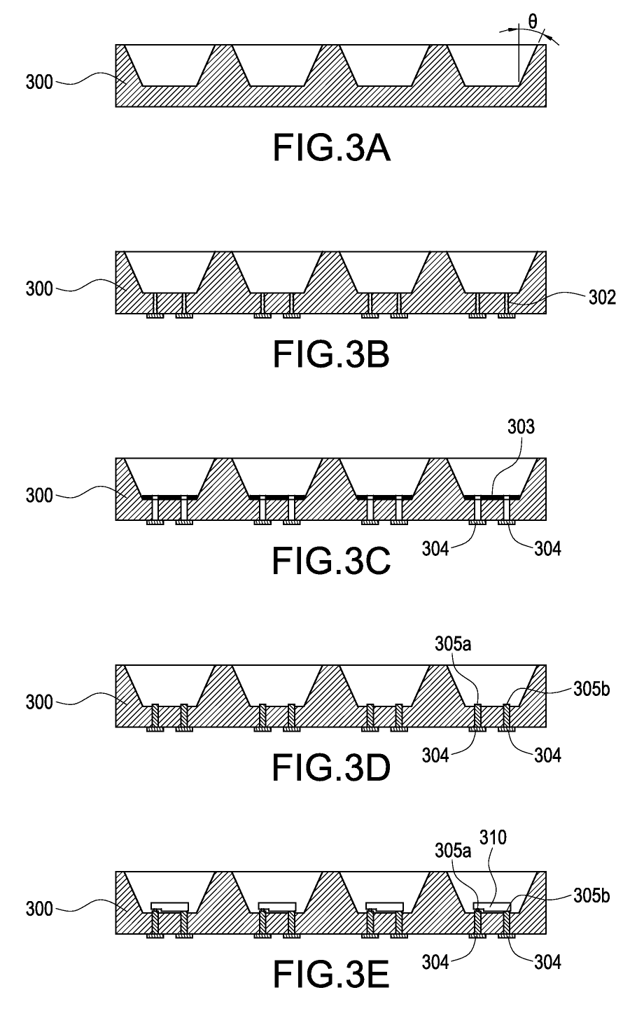

In step 200, with reference also to FIG. 3A, an anisotropic wet etching is performed on a silicon wafer to fabricate a silicon groove array 300 with a plurality of grooves. The anisotropic wet etching can be performed by KOH or TMAH solution. The silicon wafer can be an epitaxial silicon wafer and the groove has a depth of 100-300 mm and angle 2θ of 15-140 degree (namely, the angle θ shown in FIG. 3B is of 7.5-70 degree) after the anisotropic wet etching.

In step 202, with reference also to FIG. 3B, two through holes 302 are defined on the base of the groove by punching through or laser etching. Two bottom electrodes 304 are formed below the through holes 302 by using Ti—Al—Au alloy.

In step 204, with reference also to FIG. 3C, patterns 303 are defined by photo resist on the top face of the groove and the patterns 303 are used as mask for etching the through holes 302.

In step 206, with reference also to FIG. 3D, conductive material is placed into the through holes and photo resist is removed to form vias 305, where the vias 305 comprise contact pads 305a and 305b thereon. The conductive material can be, for example, formed by electro plating or deposition.

In step 208, with reference also to FIG. 3E, an LED die is flip-chip mounted in each groove of the silicon groove array 300 with the electrodes (not labeled in this figure) thereof electrically connected to the contact pads 305a and 305b. Therefore, the LED die can get electrical power from the bottom electrodes 304. The LED die, for example, can be a GaN-based blue LED die and the cathode and the anode of the LED are on the same face of the LED.

In step 208, with reference also to FIG. 3E, the silicon groove array 300 mounted with the LED dies 310 is singularized into a plurality of silicon submounts 300a, where each silicon submount 300a comprises one or more grooves, depending on practical need.

In step 212, with reference also to FIG. 3F, a protective glue 320 is applied to the resulting structure and the protective glue 320 provides a flat top surface for the silicon submount 300a. The protective glue 320 can be multiple layers of silicone, which are applied in different sub-steps and have different refractive indices. Therefore, the protective glue 320 also provides index matching effect by selecting silicone layers with proper index.

In step 214, with reference also to FIG. 3G, a phosphor layer 322 is formed on the resulting structure by printing. According to a preferred embodiment of the present invention, the phosphor layer 322 is formed on the flat top surface of the protective glue 320 by using a scraping knife to scrape a phosphor solution on the protective glue 320 in lithography room (yellow room). The phosphor solution is prepared by mixing silicone and YAG yellow phosphor powder in 100:13 weight ratio. The phosphor layer 322 is formed with 50-200 micrometer thickness and has a distance of 100 micrometer with respect to the LED die 310.

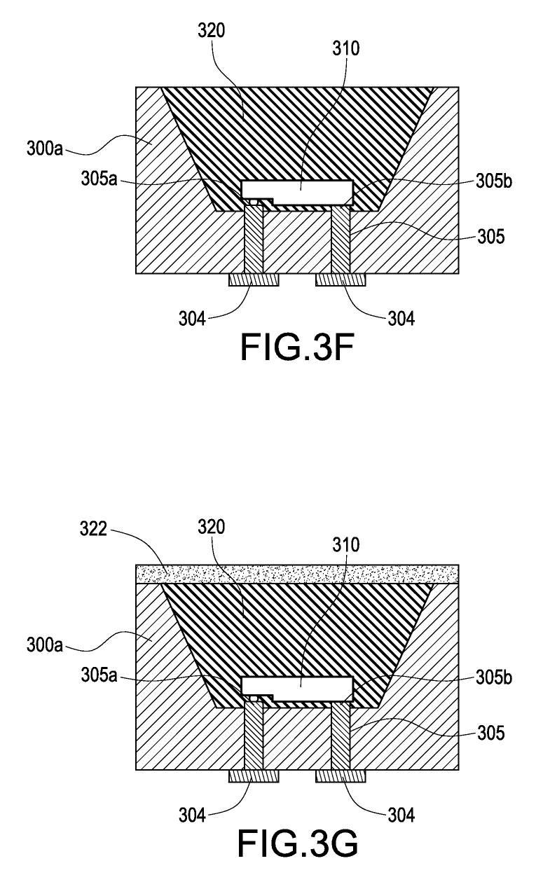

FIG. 4 shows an LED package according to the present invention. The protective glue 320 provides a flat top surface and a phosphor layer 322 is printed on the protective glue 320. Therefore, the LED package according to the present invention can provide a uniform light conversion effect

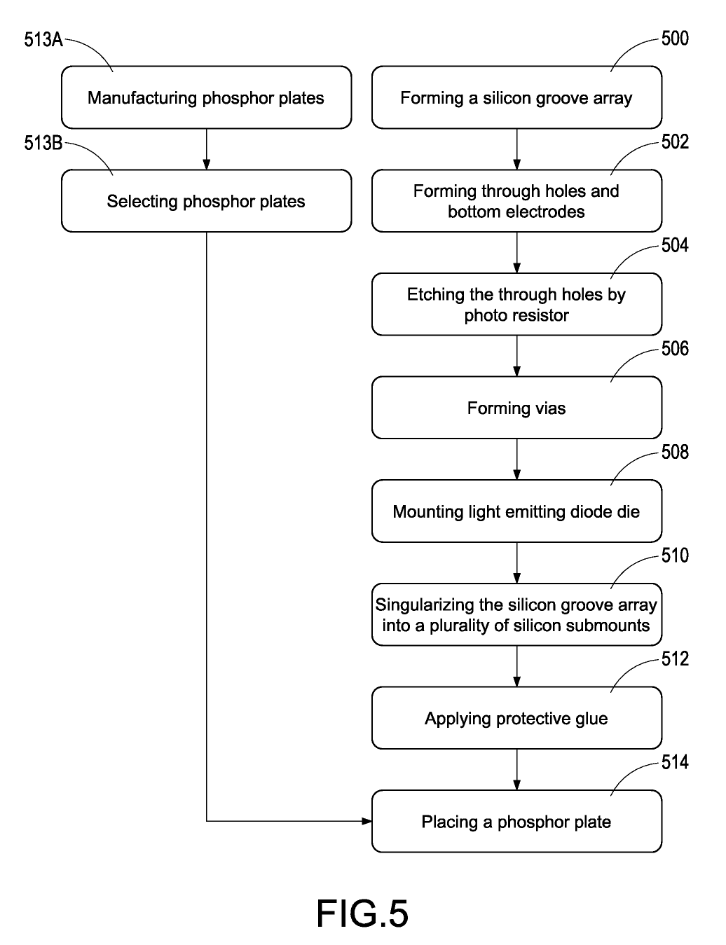

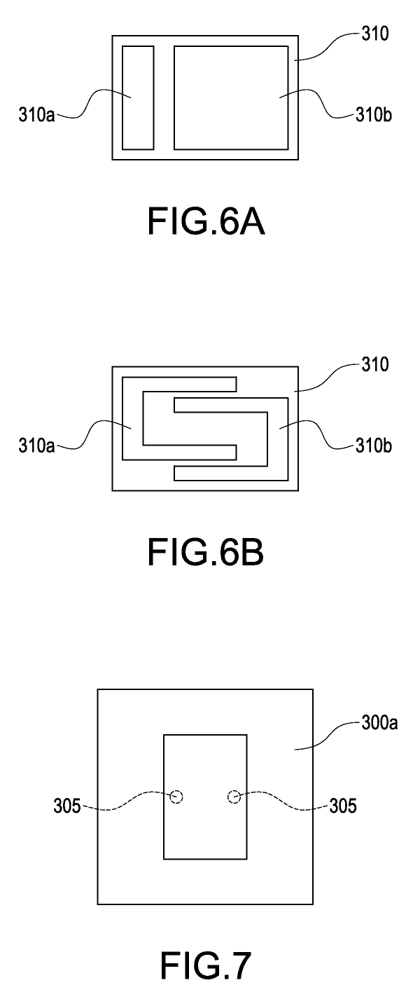

FIGS. 6A and 6B show the electrodes on the LED die 310. FIG. 7 shows the top view of the vias 305 (provided that the contact pads 305a and 305b are removed). The electrodes 310a and 310b of the LED die 310 are separated to prevent short circuit problem. Moreover, the electrodes 310a and 310b of the LED die 310 have various layouts to enhance illumination efficiency. Moreover, two vias 305 are provided for each LED die 310 to facilitate the connection of external electrical power to the LED die 310. Therefore, the LED die 310 in this kind of package is suitable for SMD application.

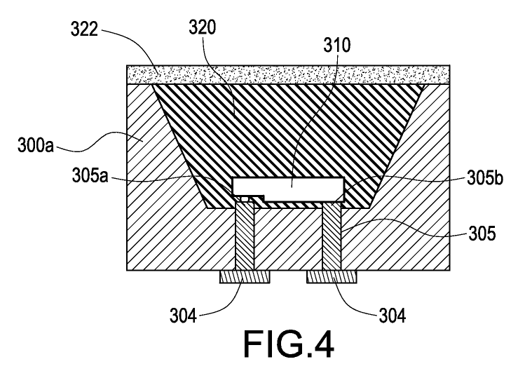

FIG. 5 shows the flowchart of the method for manufacturing flip-chip light emitting diode package according to the second preferred embodiment of the present invention. The flowchart shown in FIG. 5 is similar to that shown in FIG. 2 except that the step 214 in FIG. 2 is replaced by a step of attaching phosphor plate. The phosphor plate can be manufactured in advance by mold pressing with steel mold or glass mold, and is then cured (step 513A). The cured phosphor plate is classified with predetermined color temperature parameters (step 513B). In the prior art method of manufacturing light emitting diode package, the phosphor is mixed with epoxy and then the phosphor mixture is applied to a cup or a groove by dispenser. Therefore, the test of color temperature can be performed only when the whole package is finished. This is cumbersome and renders instability to the manufacture process. In this preferred embodiment, the phosphor plate is cured and has fixed color temperature parameter. Therefore, the phosphor plate can be selected with predetermined color temperature parameter and then the phosphor plate with desired color temperature parameter is placed on the flat surface of the protective glue to enhance yield of light emitting diode package.

Although the present invention has been described with reference to the preferred embodiment thereof, it will be understood that the invention is not limited to the details thereof. Various substitutions and modifications have suggested in the foregoing description, and other will occur to those of ordinary skill in the art. Therefore, all such substitutions and modifications are intended to be embraced within the scope of the invention as defined in the appended claims.

What is claimed is:

1. A method for manufacturing flip-chip light emitting diode package, comprising:
providing a silicon groove array with a plurality of grooves;
forming a plurality of vias in each of the grooves and forming contact pads corresponding to the vias on bottom of the groove;
mounting a light emitting diode die on a metal block, wherein electrodes of the light emitting diode are arranged with respect to the vias;
singularizing the silicon groove array into a plurality of silicon submounts, wherein each of the silicon submounts comprises at least one groove;
filling the groove with a protective glue such that the silicon submount has a flat surface; and
printing a phosphor layer on the protective glue.

2. The method in claim 1, where the step of forming the vias comprises:
forming through holes on a base of the groove by punching through or laser etching; and
forming bottom electrodes at locations corresponding to the through holes by using Ti—Al—Au alloy.

3. The method in claim 2, further comprising:
defining patterns at a front face of the groove by photo resist;
wet-etching the through holes; and
filling conductive material into etched through holes to form the vias, where contact pads are formed on top face of the vias.

4. The method in claim 3, wherein the electrodes of the LED die are electrically connected to the contact pads when the LED die is flip-chip mounted in the groove.

5. The method in claim 3, wherein the conductive material is formed by electro plating or deposition.

6. The method in claim 1, wherein the phosphor layer is printed in a yellow room.

7. The method in claim 6, wherein the phosphor layer is formed by using a scraping knife to scrape a phosphor solution.

8. The method in claim 7, wherein the phosphor solution is prepared by mixing a silicone and a YAG yellow phosphor powder in a weight ratio of 100:13.

9. The method in claim 1, wherein the silicon groove array is fabricated by wet etching a silicon wafer; and the groove has a depth of 100-300 mm and an angle of 15-140 degree.

10. The method in claim 1, wherein the phosphor layer is formed with 50-200 micrometer thickness and has a distance of 100 micrometer with respect to the light emitting diode die.

11. A method for manufacturing light emitting diode package, comprising:
providing a silicon groove array with a plurality of grooves;
forming a plurality of vias in each of the grooves and forming contact pads corresponding to the vias on bottom of the groove;
mounting a light emitting diode die on a metal block, wherein electrodes of the light emitting diode die are arranged with respect to the vias;
singularizing the silicon groove array into a plurality of silicon submounts, wherein each of the silicon submounts comprises at least one groove;
filling the groove with a protective glue such that the silicon submount has a flat top surface; and
providing a phosphor plate with a predetermined color temperature parameter on the protective glue.

12. The method in claim 11, wherein the phosphor plate is formed by mold pressing and is cured; and the phosphor plate is then subjected to a color temperature measurement.

13. The method in claim 11, wherein the phosphor plate is made of yellow YAG powder.

14. The method in claim 11, wherein the protective glue is formed by applying multiple layers of silicone, wherein the multiple layers of silicone have different refractive indices to provide index matching effect.

15. A package for flip-chip packaging a light emitting diode die, comprising:
a silicon submount comprising at least one groove therein;
a plurality of vias formed on a base of the groove, wherein the light emitting diode die is flip-chip mounted on the groove with electrodes of the LED die electrically connected to the vias;
a protective glue formed in the groove and having a flat top face; and
a phosphor layer arranged atop the protective glue.

16. The package in claim 15, wherein a bottom electrode is provided below each of the vias, wherein the bottom electrode is made of Ti—Al—Au alloy.

17. The package in claim 15, wherein the protective glue is made of multiple layers of silicone, wherein the multiple layers of silicone have different refractive indices to provide index matching effect.

18. The package in claim 15, wherein the groove has a depth of 100-300 mm and an angle of 15-140 degree.

19. The package in claim 15, wherein the phosphor layer is formed with 50-200 micrometer thickness and has a distance of 100 micrometer with respect to the light emitting diode die.

20. The device in claim 15, wherein the phosphor plate is made of yellow YAG powder.
